(19) United States
(12) Patent Application Publication
(10) Pub. No.: US 2006/0079012 A1
(43) Pub. Date: Apr. 13, 2006

(54) Method of manufacturing carbon nanotube field emission device

(76) Inventors: Tae-Won Jeong, Seoul (KR); Jung-Na Heo, Yongin-si (KR); Jeong-Hee Lee, Seongnam-si (KR)

Correspondence Address: Robert E. Bushnell, Suite 300, 1522 K Street, N.W., Washington, DC, 20005, US

(21) Appl. No.: 11/121,089

(22) Filed: May 4, 2005

(30) Foreign Application Priority Data
May 6, 2004 (KR) 10-2004-0031670

(51) Int. Cl. H01L 21/00

(52) U.S. Cl. 438/20

(57) ABSTRACT

A carbon nanotube emitter and a method of manufacturing a carbon nanotube field emission device using the carbon nanotube emitter. Powdered carbon nanotubes are adsorbed onto a first substrate. A metal is deposited on the carbon nanotubes. The resultant structure is pressure-bonded to a surface of a cathode. The first substrate is spaced apart from a second substrate to tense the carbon nanotubes, so that the carbon nanotubes are perpendicular to the first substrate.

### CLAIM OF PRIORITY

This application claims the priority of Korean Patent Application No. 10-2004-0031670, filed on May 6, 2004, in the Korean Intellectual Property Office, the disclosure of which is incorporated herein in its entirety by reference.

### BACKGROUND OF THE INVENTION

1. Field of the Invention

The present invention relates to a method of manufacturing a carbon nanotube (carbon nanotube) field emission device, and more particularly, to a method of manufacturing a field emission device in which a thermal impact caused by a high temperature process is reduced.

2. Description of the Related Art

Carbon nanotubes (carbon nanotubes) are widely used as field emitters for backlights used in field emission displays (FEDs) and liquid crystal displays (LCDs). Such carbon nanotubes have good electron emission characteristics and chemical and mechanical durability. The properties and applications of such carbon nanotubes have been studied.

Conventional field emitters are typically micro tips made of a metal such as molybdenum (Mo). However, the life span of such a micro tip is shortened due to effects of an atmospheric gas, a non-uniform electric field, and the like. Also, the work function of the micro tip must be reduced to drive the micro tip at a low voltage. However, there is a limit to reducing the work function. To solve these problems, carbon nanotubes having a high aspect ratio, high durability, and high conductivity are preferably adopted as field emitters.

In order to obtain a high current density from carbon nanotube emitters, carbon nanotubes must be uniformly distributed and be arranged perpendicularly to a substrate. In particular, the carbon nanotubes must electrically contact the substrate (or a cathode) such that all of the carbon nanotubes emit electrons.

The carbon nanotube emitters are generally grown from the substrate using chemical vapor deposition (CVD). The carbon nanotube emitters may be manufactured using a paste obtained by combining carbon nanotubes with a resin. This method is easier and less costly than CVD and thus preferred to CVD.

U.S. Pat. No. 6,339,281 entitled Method for fabricating triode-structure carbon nanotube field emitter array to Lee et al. discloses a field emitter array using a carbon nanotube paste and a method of fabricating the same. U.S. Pat. No. 6,440,761 entitled Carbon nanotube field emission array and method for fabricating the same to Choi et al. discloses a field emission array using carbon nanotubes obtained using a growing method and a method of fabricating the same.

Carbon nanotubes are generally grown from a substrate using CVD. Here, CVD is performed at a high temperature of more than 500° C. to increase the purity of the carbon nanotubes. Thus, a thermal impact on the substrate or a structure on the substrate is inevitable during CVD. When the CVD is performed at a low temperature, the purity of the carbon nanotubes is reduced. Therefore, CVD at a low temperature is not preferable. Furthermore, CVD equipment used for obtaining highly pure carbon nanotubes is high-priced, and thus CVD has a high manufacturing cost.

A carbon nanotube paste can be coated on a substrate (or a cathode) using screen printing, photolithography, or the like. Since the carbon nanotube paste includes various kinds of organic and inorganic solvents, it is difficult to obtain highly pure carbon nanotube electron emitters.

### SUMMARY OF THE INVENTION

It is therefore an object of the present invention to provide an improved method of manufacturing a carbon nanotube emitter and a a carbon nanotube field emission device.

It is another object of the present invention to provide carbon nanotube emitters having high purity and good electric characteristics and a method of manufacturing a device using the same.

It is also an object of the present invention to provide carbon nanotube emitters with a simple manufacturing process and being capable of thermally protecting other components including a substrate, and a method of manufacturing a device using the same.

According to an aspect of the present invention, there is provided a method of manufacturing carbon nanotube emitters, including: adsorbing carbon nanotubes onto a first substrate; forming a second metal layer on a second substrate; forming a first metal layer on one of the carbon nanotubes and the second metal layer; pressing the first substrate against the second substrate; spacing the first substrate apart from the second substrate to cause the carbon nanotubes to be perpendicular to the second substrate; and further spacing the first substrate apart from the second substrate to separate the carbon nanotubes from the first substrate.

According to another aspect of the present invention, there is provided a method of manufacturing carbon nanotube emitters, including: adsorbing powdered carbon nanotubes onto a first substrate; forming a first metal layer in a predetermined pattern on the carbon nanotubes; forming a second metal layer on a second substrate; press-bonding the first metal layer to the second metal layer; spacing the first substrate apart from the second substrate to make the carbon nanotubes perpendicular to the second substrate; and further spacing the first substrate from the second substrate to separate the carbon nanotubes from the first substrate.

According to also another aspect of the present invention, there is provided a method of manufacturing carbon nanotube emitters, including: adsorbing powdered carbon nanotubes onto a first substrate; forming a second metal layer on a second substrate; forming a first metal layer in a predetermined pattern on the second metal layer; pressing the carbon nanotubes to bond the carbon nanotubes on the first substrate to the first metal layer; spacing the first substrate apart from the second substrate to make the carbon nanotubes perpendicular to the second substrate; and further spacing the first substrate from the second substrate to separate the carbon nanotubes from the first substrate.

According to still another aspect of the present invention, there is provided a method of manufacturing a carbon nanotube field emission device including a front plate including an inside surface on which an anode is formed, a rear plate which is spaced apart from the front plate and includes an inside surface on which a cathode is formed, and electron emitters which are formed of carbon nanotubes on the cathode. The method includes: forming a cathode on a rear plate; adsorbing powdered carbon nanotubes onto a stamp substrate; depositing a first metal on the carbon nanotubes to form a first metal layer on the carbon nanotubes; pressure-bonding the first metal layer on the stamp substrate to the cathode on the rear plate; spacing the stamp substrate from the rear plate to make the carbon nanotubes perpendicular to the cathode on the rear plate; and further spacing the stamp substrate from the rear plate to separate the carbon nanotubes from the stamp substrate.

According to yet another aspect of the present invention, there is provided a method of manufacturing a carbon nanotube field emission device including a front plate including an inside surface on which an anode is formed, a rear plate which is spared apart from the front plate and includes an inside surface on which a cathode is formed, and an electron emitter formed by carbon nanotubes on the cathode. The method includes: forming a cathode on a rear plate; forming a metallic bonding layer on the cathode; adsorbing powdered carbon nanotubes onto a stamp substrate; pressure-bonding the carbon nanotubes on the stamp substrate to the metallic bonding layer on the cathode; spacing the stamp substrate from the rear plate to make the carbon nanotubes perpendicular to the cathode; and further spacing the stamp substrate from the rear plate to separate the carbon nanotubes from the stamp substrate.

The adsorption of the carbon nanotubes onto the stamp substrate includes: mixing the powdered carbon nanotubes with a liquid dispersing agent; coating the stamp substrate with the dispersed carbon nanotubes; and removing the liquid dispersing agent to adsorb the carbon nanotubes onto the stamp substrate.

In the bonding, the second metal layer is heated together with the second substrate to a predetermined temperature to perform hot pressure bonding. As a result, carbon nanotubes can be efficiently bonded to the second substrate.

According to yet another aspect of the present invention, there is provided a method of manufacturing a carbon nanotube field emission device including a front plate including an inside surface on which an anode is formed, a rear plate which is spared apart from the front plate and includes an inside surface on which a cathode is formed, and electron emitters formed of carbon nanotubes on the cathode. The method includes: forming the cathode on the inside surface of the rear plate; adsorbing powdered carbon nanotubes facing the cathode onto an additional stamp substrate; depositing a metal on the carbon nanotubes dispersed on the stamp substrate to form a first metal layer on the carbon nanotubes; pressure-bonding the first metal layer on the stamp substrate to the cathode of the rear plate; spacing the stamp substrate from the rear plate to tense the carbon nanotubes that are bonded to the cathode on the rear plate by the first and second metal layers; and further spacing the stamp substrate from the rear plate to separate the carbon nanotubes from the stamp substrate.

The adsorption of the carbon nanotubes onto the first substrate or the stamp substrate includes: mixing the powdered carbon nanotubes with a liquid dispersing agent; coating the first substrate or the stamp substrate with the dispersed carbon nanotubes; and removing the liquid dispersing agent to adsorb the carbon nanotubes onto the first substrate or the stamp substrate. The liquid dispersing agent is an organic solvent, for example, ethanol, or an inorganic solvent such as water.

### BRIEF DESCRIPTION OF THE DRAWINGS

A more complete appreciation of the present invention, and many of the above and other features and advantages of the present invention, will be readily apparent as the same becomes better understood by reference to the following detailed description when considered in conjunction with the accompanying drawings in which like reference symbols indicate the same or similar components, wherein:

FIGS. 1A through 1I illustrate a method of manufacturing a field emission device according to an embodiment of the present invention;

FIG. 2A is a scanning electron microscope (SEM) image illustrating carbon nanotubes which were coated and dried on a stamp substrate that is a first substrate, using an organic dispersing agent, according to an embodiment of the present invention;

FIG. 2B is a SEM image illustrating carbon nanotube emitters, according to an embodiment of the present invention;

FIGS. 3A through 3F illustrate a method of manufacturing a field emission device, according to another embodiment of the present invention;

FIG. 4 is a SEM image illustrating a pattern of carbon nanotube emitters, according to an embodiment of the present invention;

FIGS. 5A through 5F illustrate a method of manufacturing a field emission device, according to still another embodiment of the present invention; and

FIG. 6 is a schematic view of an electronic device adopting a carbon nanotube field emission device according to an embodiment of the present invention.

### DETAILED DESCRIPTION OF THE PREFERRED EMBODIMENTS

Hereinafter, a method of manufacturing a carbon nanotube emitter and a method of manufacturing a field emission device adopting the carbon nanotube emitter according to embodiments of the present invention will be described in detail with reference to the attached drawings. In the drawings, a field emission device including carbon nanotubes is exaggerated for clarity. In particular, one element may be illustrated larger than other elements when necessary and may be omitted to more clearly describe the embodiment.

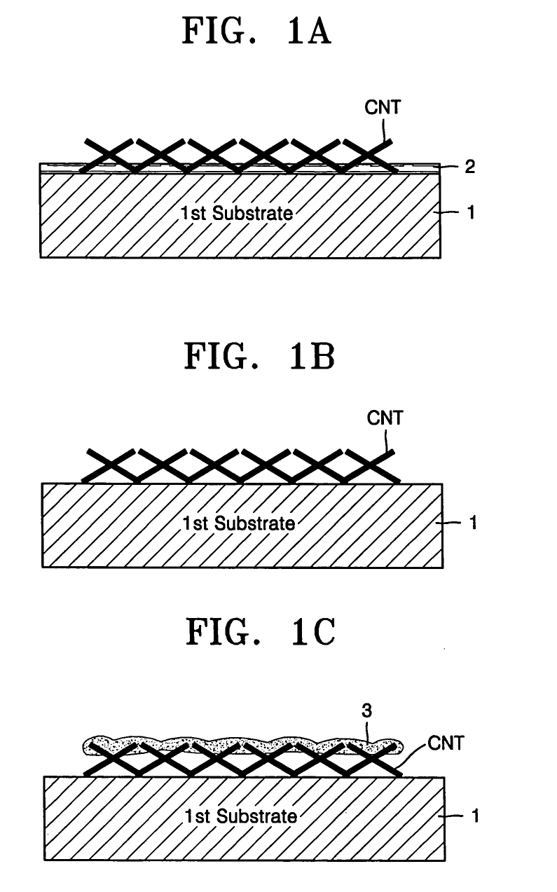

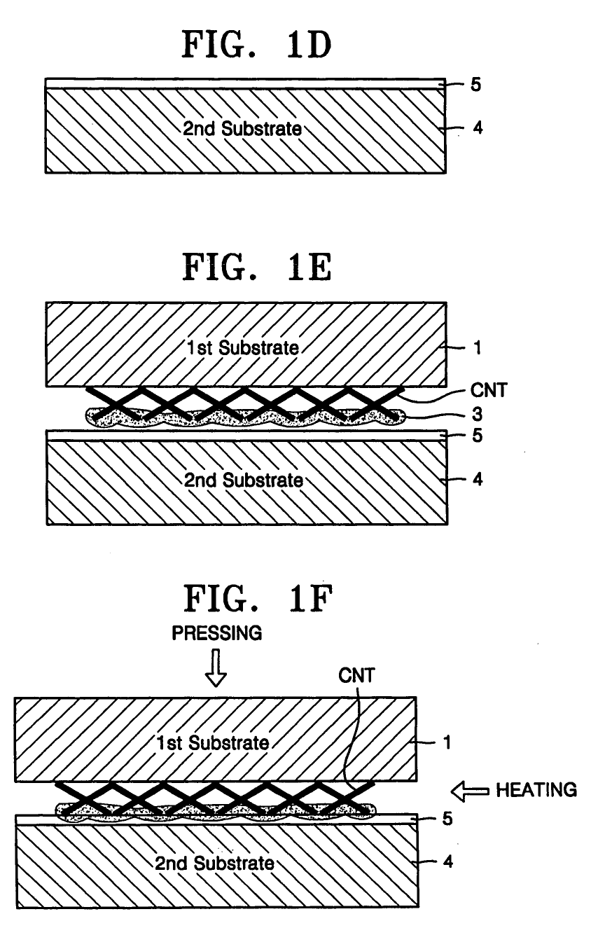

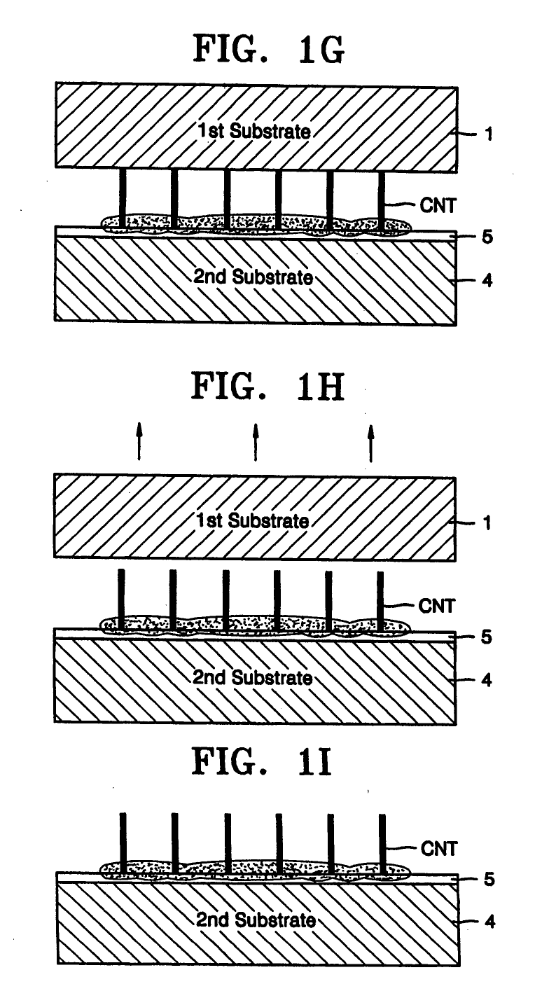

FIGS. 1A through 1I illustrate a method of manufacturing a carbon nanotube emitter, according to an embodiment of the present invention.

As shown in FIG. 1A, carbon nanotube powder is mixed with an organic dispersing agent, for example, ethanol, or an inorganic dispersing agent, for example, water 2. Next, the mixture is coated on the surface of a first substrate 1 formed of Si or sodalime glass.

As shown in FIG. 1B, the dispersing agent 2 is removed by natural or forced drying so that only carbon nanotubes remain on the first substrate 1. Here, the carbon nanotubes are attracted to the first substrate 1 by Van der Waals force, i.e., a molecular force.

As shown in FIG. 1C, a first metal layer 3 is formed of Ag or the like on the surface of the carbon nanotubes to a predetermined thickness. Here, the first metal layer 3 is formed only on an upper portion of the carbon nanotubes by adjusting an amount of deposited metal.

As shown in FIG. 1D, a second substrate 4 is prepared, and then a second metal layer 5 is formed of Ag, Cu, or Ti on the surface of the second substrate 4. Here, the second substrate 4 will be an element of a specific product according to an object to which the second substrate 4 is applied. For example, when the second substrate 4 is applied to a field emission device, the second substrate 4 is a rear plate. In this case, the second metal layer 5 is a cathode of the field emission device. Thus, on the rear plate of the field emission device used in this step, i.e., the second substrate 4 of the present embodiment, a cathode of the pattern required for the field emission device may be prepared. If necessary, a gate insulating layer and a gate electrode may be optionally formed on the rear plate. In the present embodiment, the gate insulating layer and the gate electrode may be omitted regardless of whether they are formed or not.

As shown in FIG. 1E, the first substrate 1 is turned upside down so that the carbon nanotubes contact an upper surface of the second substrate 4. Here, the second metal layer 5 of the second substrate 4 contacts the carbon nanotubes on the first substrate 1.

As shown in FIG. 1F, the first substrate 1 is pressed against the second substrate 4 to pressure-bond the first metal layer 3 on the carbon nanotubes to the second metal layer 5 on the surface of the second substrate 4. Heat is applied to the first and second metal layers 3 and 5 to achieve efficient hot pressure-bonding. The carbon nanotubes on which the first metal layer 3 is formed are strongly bonded to the second metal layer 5 due to pressure-bonding, particularly, hot pressure bonding. Here, a general presser is used as a presser for bonding.

As shown in FIG. 1G, the first substrate 1 is perpendicularly spaced apart from the second substrate 4 to tense the carbon nanotubes therebetween, thereby causing the carbon nanotubes to be perpendicular to the second substrate 4.

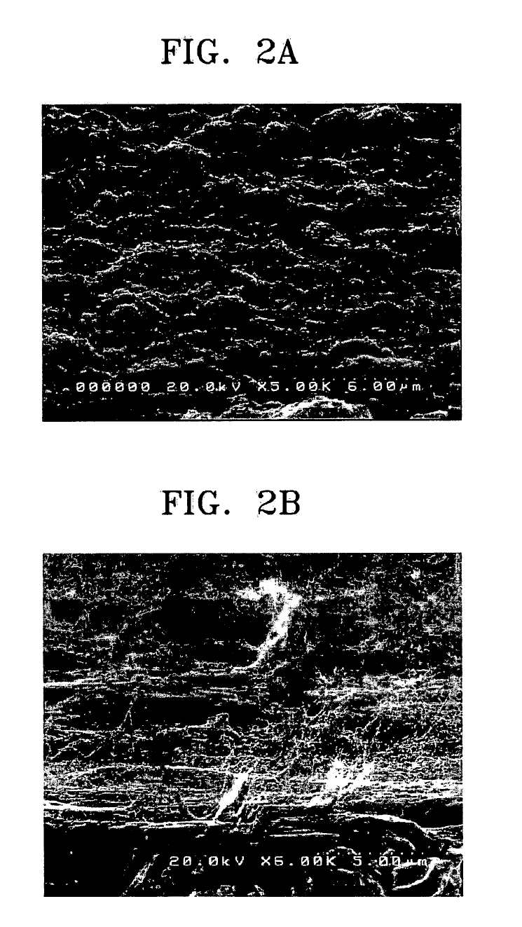

FIG. 2A is a SEM image illustrating carbon nanotubes which were coated on a first substrate or a stamp substrate along with a dispersing agent and then are dried. The carbon nanotubes shown in FIG. 2A correspond to the carbon nanotubes of FIG. 1B.

FIG. 2B is a SEM image illustrating carbon nanotube emitters that were manufactured from the first substrate of FIG. 2A. The carbon nanotube emitters of FIG. 2B include a Ti metal layer formed as a cathode on a silicon substrate and carbon nanotubes bonded to the Ti metal layer by Ag. The Ti and Ag metal layers each have a thickness of 1000 to 2000 Å. During bonding, a pressure of about 3 MPa is applied for about 60 to 270 seconds, and a temperature is adjusted to about 300° C. As shown in FIGS. 2A and 2B, the carbon nanotubes are perpendicular to the first substrate. Thus, carbon nanotubes can be manufactured perpendicular to a substrate without being grown from the substrate.

The above-described processes have been described regardless of the shape of the carbon nanotube emitters. However, carbon nanotube emitters have a predetermined shape and size, and thus a method of manufacturing such a carbon nanotube emitter is proposed.

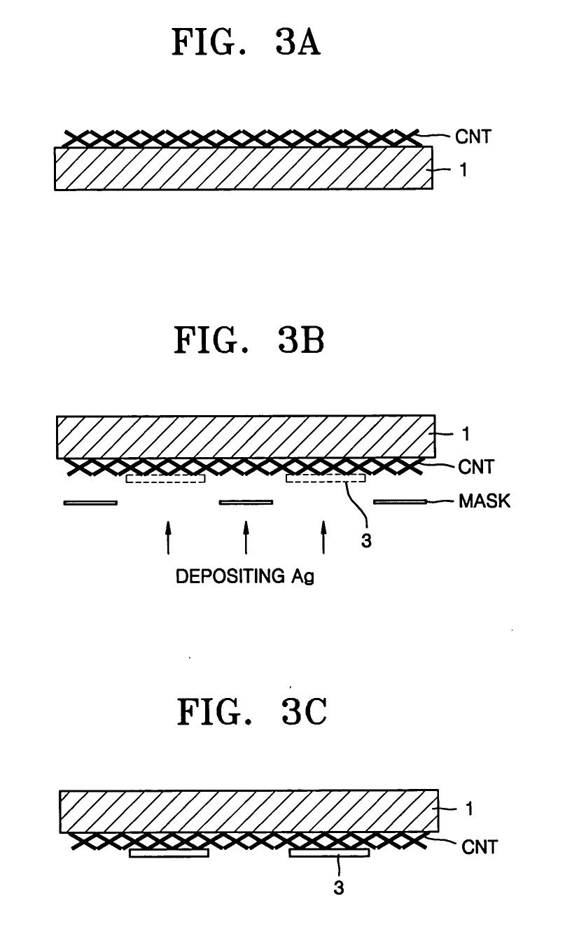

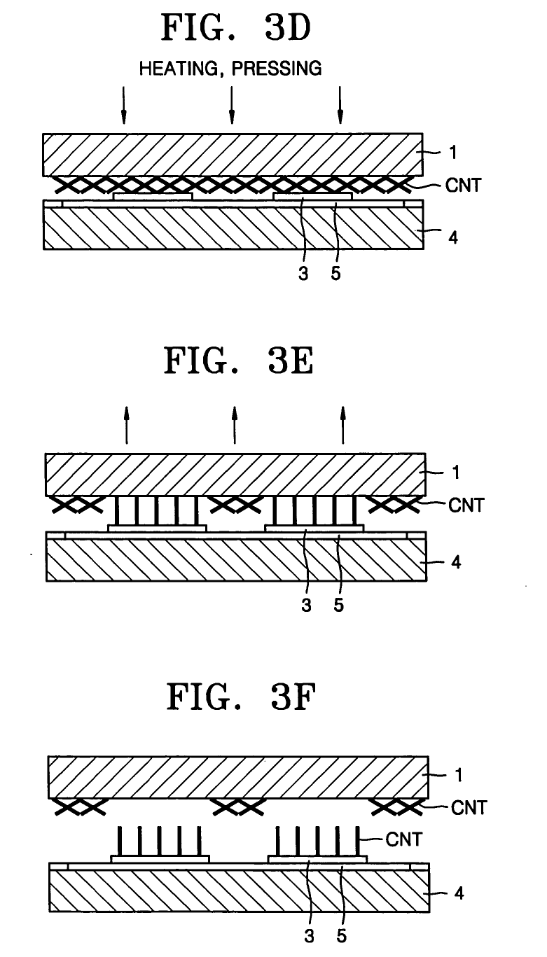

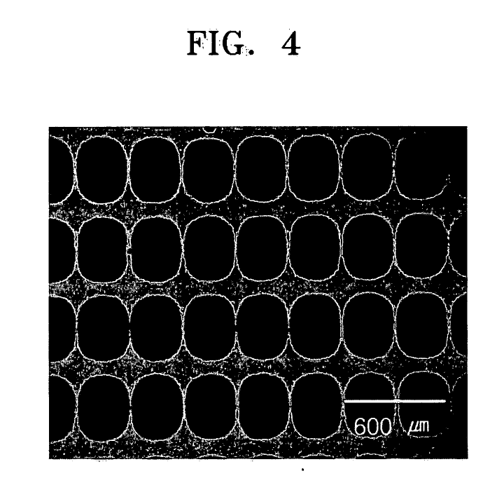

FIGS. 3A through 3F illustrate a method of manufacturing a carbon nanotube emitter of predetermined pattern, according to another embodiment of the present invention.

As shown in FIG. 3A, carbon nanotube powder, which has been dispersed in an organic or inorganic solvent, is coated on a first substrate 1 and then dried.

As shown in FIG. 3B, a first metal layer 3 with predetermined pattern is formed on a stack of the carbon nanotube powder adsorbed on the first substrate 1. Here, the first metal layer 3 is formed of Ag, and a mask is positioned in front of the first substrate 1 to limit a deposition area.

After the first metal layer 3 is completed on the stack of the carbon nanotube powder as shown in FIG. 3C, the first substrate 1 is pressed against a second substrate 4 using the previously described method as shown in FIG. 3D. A second metal layer 5, i.e., a cathode, is formed on an upper surface of the second substrate 4, and the first metal layer 3 with predetermined pattern is bonded to the cathode.

As shown in FIG. 3E, the first substrate 1 is perpendicularly spaced apart from the second substrate 4 to tense carbon nanotubes therebetween, so that the carbon nanotubes are perpendicular to the second substrate 4. The tensed carbon nanotubes, i.e., the carbon nanotubes perpendicular to the first substrate 1, are carbon nanotubes on which the first metal layer 3 has been formed, and the rest of the carbon nanotubes remain on the inside surface of the first substrate 1.

As shown in FIG. 3F, the first substrate 1 is further spaced apart from the second substrate 4 to separate the carbon nanotubes 1 from the first substrate 1 using a molecular force.

FIG. 4 is a SEM image illustrating carbon nanotube emitters formed on a second substrate, according to an embodiment of the present invention. In a method of manufacturing carbon nanotube emitters according to the present invention, the carbon nanotube emitters can be perpendicularly arranged without being grown, and in particular, carbon nanotubes can be transferred to the second substrate with a desired pattern due to a pattern of a first metal layer.

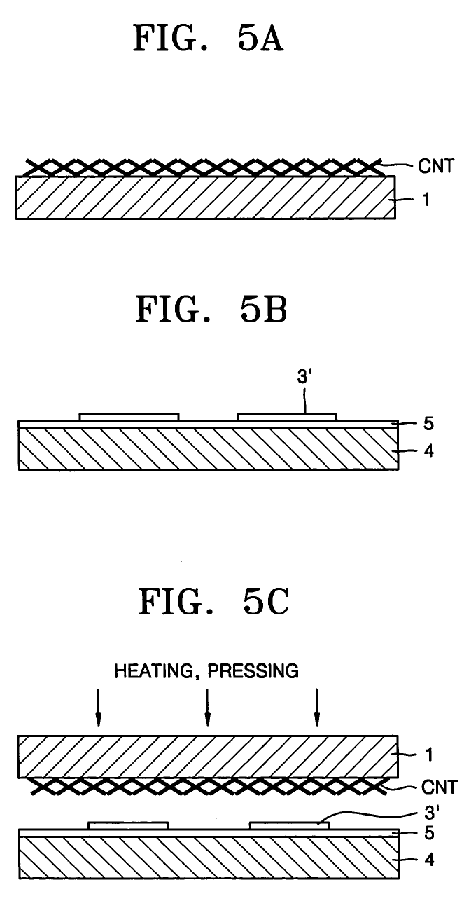

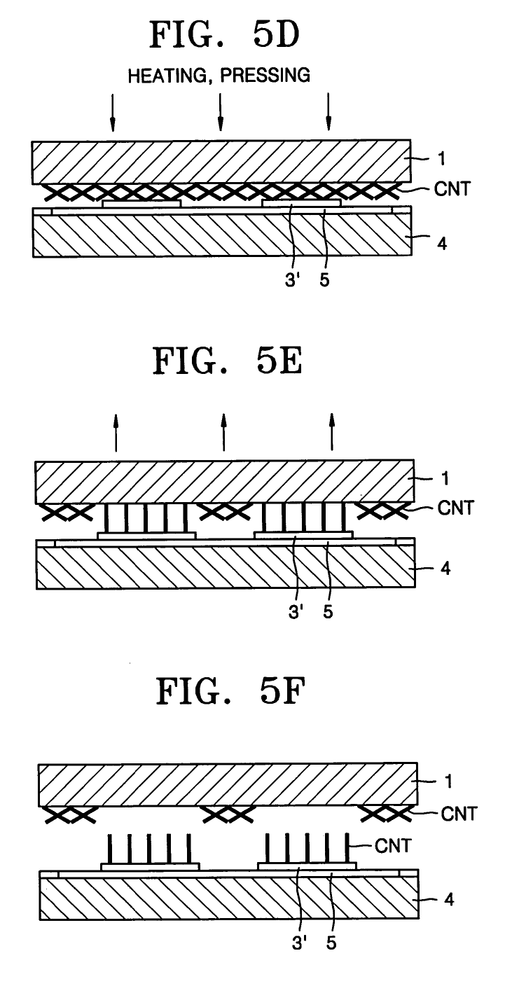

FIGS. 5A through 5F illustrate a method of manufacturing carbon nanotube emitters with a predetermined pattern, according to still another embodiment of the present invention.

As shown in FIG. 5B, a second metal layer 5, i.e., a cathode, is formed on the surface of a second substrate 4. Next, a first metal layer 3′ is formed on the second metal layer 5. The first metal layer 3′ is formed of a material for bonding carbon nanotubes by pressing. The material for the first metal layer 3′ is preferably Ag.

When a surface of the first substrate 1 on which carbon nanotubes are formed faces the surface of the second substrate 4 on which the first and second metal layers 3′ and 5 are formed as shown in FIG. 5C, the first substrate 1 and the second substrate 4 are pressed together using the previously described method as shown in FIG. 5D. The carbon nanotubes adsorbed on the surface of the first substrate 1 are bonded to the first metal layer 3′ formed on the second substrate 4. Here, the carbon nanotubes are not bonded to regions where the first metal layer 3′ has not been formed.

As shown in FIG. 5E, the first substrate 1 is perpendicularly spaced apart from the second substrate 4 to tense the carbon nanotubes therebetween, so that the carbon nanotubes are perpendicular to the second substrate 4. Here, the tensed carbon nanotubes, i.e., the carbon nanotubes perpendicular to the first substrate 1, are carbon nanotubes bonded to the first metal layer 3′, and the remaining carbon nanotubes remain on the inside surface of the first substrate 1.

As shown in FIG. 5F, the first substrate 1 is further spaced apart from the second substrate 4 to separate the carbon nanotubes from the first substrate 1 using a molecular force.

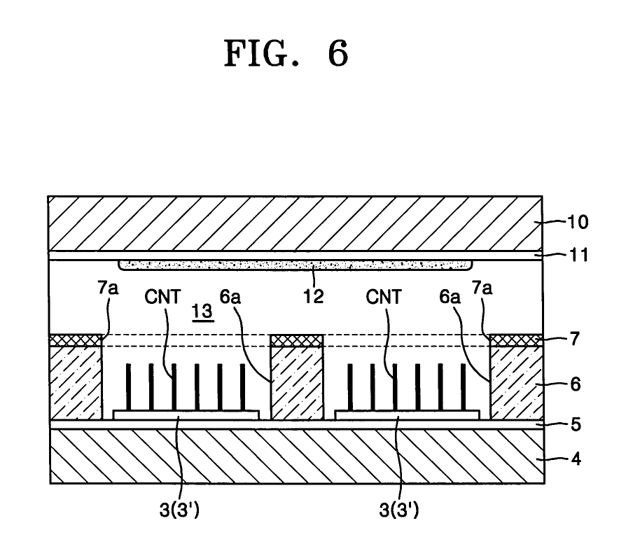

FIG. 6 is a schematic cross-sectional view of a carbon nanotube field emission device, according to an embodiment of the present invention. Referring to FIG. 6, a rear plate 4 (the second substrate 4 in the above-described process) is spaced apart from a front plate 10. A vacuum space 13 in which electrons move is formed between the rear plate 4 and the front plate 10.

An anode 11 is formed on the surface of the front plate 10 facing the rear plate 4, and a fluorescent layer 12 is formed on the anode 11. A cathode 5 (the second metal layer 5 in the above-described process) is formed on the surface of the rear plate 4 facing the front plate 10. A gate insulating layer 6 having throughholes 6a is formed on the cathode 5 so as to be opposed to the anode 11. A gate electrode 7 having gate holes 7a corresponding to the throughholes 6a is formed on the gate insulating layer 6.

Carbon nanotubes which are perpendicularly arrayed are provided at the bottoms of the throughholes 6a. The carbon nanotubes are bonded to a metallic boning layer 3 (3′) (the first metal layer 3 or 3′ in the above-described processes) bonded to the surface of the cathode 5.

A method of manufacturing a carbon nanotube field emission device having the above-described structure is performed according to conventional processes except for processes of forming a cathode and carbon nanotubes on the rear plate 4, i.e., the above-described method of manufacturing carbon nanotube emitters. In other words, carbon nanotube emitters are formed above the rear plate 4 using the above-described method, and then a gate insulating layer, a gate electrode, and the like are formed. If necessary, the cathode 5 and the gate insulating layer 6 may be formed on the rear plate 4, and then the carbon nanotube emitter may be formed.

The present invention may be applied to the manufacturing of a backlight device of a passive light emitting display such as an LCD. The backlight device manufactured according to the present invention has the same structure as a general backlight device except for an electron emitter used for exciting a fluorescent substance which is manufactured according to a method of manufacturing a carbon nanotube emitter as described above.

As described above, in a method of manufacturing a carbon nanotube field emission device, according to the present invention, carbon nanotube emitters can be manufactured perpendicularly to a substrate without using high temperature CVD. Moreover, since an organic or inorganic binder (except for an organic solvent) is not used, the carbon nanotube emitters can be highly pure. Thus, the carbon nanotube emitters can have a predetermined pattern in a large area without being limited by the size of the substrate, which is limited when using CVD. Also, since CVD is not adopted, high-priced equipment is not necessary. As a result, the carbon nanotube emitters can be manufactured at a relatively low cost. When carbon nanotube emitters manufactured using CVD require subsequent processes such as an activation process. However, in the present invention, such subsequent processes are not necessary. Furthermore, the carbon nanotube emitters can be manufactured at a low temperature. Thus, a thermal impact on the substrate and the other components caused by a high temperature process can be reduced.

In particular, in the carbon nanotube emitters of the present invention, carbon nanotubes can be bonded to a cathode by a bonding material having high conductivity. Thus, the carbon nanotube emitters can have good electric characteristics and emit electrons from most of the carbon nanotubes. As a result, a uniform current can be generated.

The method of manufacturing the carbon nanotube emitter according to the present invention can be applied to various fields. For example, the method of the present invention can be applied to a field emission display, a flat lamp, an electron emitter, and so forth. The method of the present invention may be independently performed or may be generally included in processes used in the various fields.

What is claimed is:

1. A method of manufacturing a carbon nanotube emitter, comprising:
adsorbing carbon nanotubes onto a first substrate;
forming a second metal layer on a second substrate;
forming a first metal layer on one of the carbon nanotubes and the second metal layer;
pressing the first substrate against the second substrate;
spacing the first substrate apart from the second substrate to cause the carbon nanotubes to be perpendicular to the second substrate; and
further spacing the first substrate apart from the second substrate to separate the carbon nanotubes from the first substrate.

2. The method of claim 1, wherein the adsorption of the carbon nanotubes onto the first substrate comprises:
mixing the carbon nanotubes with a dispersing agent;
coating the first substrate with the dispersed carbon nanotubes; and
removing the dispersing agent to adsorb the carbon nanotubes onto the first substrate.

3. The method of claim 2, wherein the dispersing agent is one of an organic solvent and an inorganic solvent.

4. The method of claim 3, wherein the organic solvent is ethanol.

5. The method of claim 1, wherein the first metal layer comprises Ag.

6. The method of claim 1, wherein the second metal layer comprises a metal selected from Ag, Cu, and Ti.

7. The method of claim 1, wherein the step of pressing the first substrate against the second substrate further comprises heating at least one of the first metal layer and the second metal layer.

8. The method of claim 1, wherein, in the step of forming the first metal layer, the first metal layer is formed on the carbon nanotubes.

9. The method of claim 8, wherein the first metal layer is formed in a predetermined pattern.

10. The method of claim 9, wherein the formation of the first metal layer comprises positioning a mask in front of the first substrate and depositing a first metal on the carbon nanotubes to form the predetermined pattern.

11. The method of claim 1, wherein, in the step of forming the first metal layer, the first metal layer is formed on the second metal layer.

12. The method of claim 11, wherein the first metal layer is formed in a predetermined pattern.

13. A carbon nanotube emitter manufactured by the method of claim 1.

14. A method of manufacturing a carbon nanotube emitter, comprising:
adsorbing powdered carbon nanotubes onto a first substrate;
forming a first metal layer in a predetermined pattern on the carbon nanotubes;
forming a second metal layer on a second substrate;
press-bonding the first metal layer to the second metal layer;
spacing the first substrate apart from the second substrate to make the carbon nanotubes perpendicular to the second substrate; and
further spacing the first substrate from the second substrate to separate the carbon nanotubes from the first substrate.

15. A method of manufacturing a carbon nanotube emitter, comprising:
adsorbing powdered carbon nanotubes onto a first substrate;
forming a second metal layer on a second substrate;
forming a first metal layer in a predetermined pattern on the second metal layer;
pressing the carbon nanotubes to bond the carbon nanotubes on the first substrate to the first metal layer;
spacing the first substrate apart from the second substrate to make the carbon nanotubes perpendicular to the second substrate; and
further spacing the first substrate from the second substrate to separate the carbon nanotubes from the first substrate.

16. The method of claim 15, wherein the adsorption of the carbon nanotubes on the first substrate comprises.
mixing the powdered carbon nanotubes with a liquid dispersing agent;
coating the first substrate with the dispersed carbon nanotubes; and
removing the liquid dispersing agent to adsorb the carbon nanotubes onto the first substrate.

17. A method of manufacturing a carbon nanotube field emission device, comprising:
forming a cathode on a rear plate;
adsorbing powdered carbon nanotubes onto a stamp substrate;
depositing a first metal on the carbon nanotubes to form a first metal layer on the carbon nanotubes;
pressure-bonding the first metal layer on the stamp substrate to the cathode on the rear plate;
spacing the stamp substrate from the rear plate to make the carbon nanotubes perpendicular to the cathode on the rear plate; and
further spacing the stamp substrate from the rear plate to separate the carbon nanotubes from the stamp substrate.

18. The method of claim 17, wherein the adsorption of the carbon nanotubes onto the stamp substrate comprises:
mixing the powdered carbon nanotubes with a liquid dispersing agent;
coating the stamp substrate with the dispersed carbon nanotubes; and
removing the liquid dispersing agent to adsorb the carbon nanotubes onto the stamp substrate.

19. The method of claim 18, wherein the liquid dispersing agent is one of an organic solvent and an inorganic solvent.

20. The method of claim 19, wherein the step of pressure-bonding the first metal layer to the cathode further comprises heating at least one of the first metal layer and the second metal layer to a predetermined temperature.

21. The method of claim 17, wherein the first metal layer is formed in a predetermined pattern by adopting a depositing method using a mask.

22. A method of manufacturing a carbon nanotube field emission device, the method comprising:
forming a cathode on a rear plate;
forming a metallic bonding layer on the cathode;
adsorbing powdered carbon nanotubes onto a stamp substrate;
pressure-bonding the carbon nanotubes on the stamp substrate to the metallic bonding layer on the cathode;
spacing the stamp substrate from the rear plate to make the carbon nanotubes perpendicular to the cathode; and
further spacing the stamp substrate from the rear plate to separate the carbon nanotubes from the stamp substrate.

23. The method of claim 22, wherein the adsorption of the carbon nanotubes onto the stamp substrate comprises:
mixing the powdered carbon nanotubes with a liquid dispersing agent;
coating the stamp substrate with the dispersed carbon nanotubes; and
removing the liquid dispersing agent to adsorb the carbon nanotubes onto the stamp substrate.

24. The method of claim 23, wherein the liquid dispersing agent is one of an organic solvent and an inorganic solvent.

25. The method of claim 22, wherein the pressure-bonding of the carbon nanotubes to the metallic bonding layer comprises heating the metallic bonding layer to a predetermined temperature.
